(19) United States
(12) Patent Application Publication
(10) Pub. No.: US 2023/0291383 A1
(43) Pub. Date: Sep. 14, 2023

(54) FILM BULK ACOUSTIC RESONATOR AND METHOD OF MAKING FILM BULK ACOUSTIC RESONATOR

(71) Applicant: Yasuyuki SUDO, Tokyo (JP)

(72) Inventor: Yasuyuki SUDO, Tokyo (JP)

(73) Assignee: MITSUMI ELECTRIC CO., LTD., Tokyo (JP)

(21) Appl. No.: 18/177,966

(22) Filed: Mar. 3, 2023

(30) Foreign Application Priority Data
Mar. 9, 2022 (JP) 2022-036080

(51) Int. Cl. H03H 9/17; H03H 3/02

(52) U.S. Cl. CPC H03H 9/173; H03H 3/02; H03H 2003/021

(57) ABSTRACT

The present invention provides a technique for making a film bulk acoustic resonator with ease, at low cost. A film bulk acoustic resonator, according to one aspect of the present disclosure has: a substrate having a first main surface; an oxide film provided over the first main surface; and a laminated film provided over the oxide film and including a first electrode, a piezoelectric layer, and a second electrode laminated in this order, and, in this film bulk acoustic resonator, a void where the oxide film is removed is provided between the substrate and the first electrode, and the piezoelectric layer has a through-hole that communicates with the void.

### CROSS-REFERENCE TO RELATED APPLICATIONS

The present application claims priority under 35 U.S.C. § 119 to Japanese Patent Application No. 2022-036080, filed Mar. 9, 2022, the contents of which are incorporated herein by reference in their entirety.

### BACKGROUND OF THE INVENTION

### 1. Field of the Invention

The present disclosure relates to a film bulk acoustic resonator and a method of making the film bulk acoustic resonator.

### 2. Description of the Related Art

A method of making a film bulk acoustic resonator, in which a gap is provided below a lower electrode, is known (see, for example, Patent Document 1). In the method of making a film bulk acoustic resonator disclosed in patent document 1, first, a base layer is formed over a substrate. Next, a resonator assembly is formed over the base layer. The resonator assembly includes a first electrode held in contact with the base layer, a second electrode, and a piezoelectric layer held between the first and the second electrodes. Next, a resist is formed to cover the resonator assembly and the base layer, and a through-hole is formed in the resist so that part of the base layer’s surface is exposed via the through-hole. Then, an etchant is introduced via the through-hole, a space is formed by removing part of a lower part of the resonator assembly in the base layer, and the resist is removed.

### RELATED-ART DOCUMENT

### Patent Document

[Patent Document 1] Unexamined Japanese Patent Application Publication No. 2003-032060

### SUMMARY OF THE INVENTION

The present disclosure provides a technique, whereby a film bulk acoustic resonator can be made with ease, at low cost.

According to one aspect of the present disclosure, a film bulk acoustic resonator is provided. The film bulk acoustic resonator has: a substrate having a first main surface; an oxide film provided over the first main surface; and a laminated film provided over the oxide film and including a first electrode, a piezoelectric layer, and a second electrode laminated in this order, and, in this film bulk acoustic resonator, a void where the oxide film is removed is provided between the substrate and the first electrode, and the piezoelectric layer has a through-hole that communicates with the void.

According to the present disclosure, it is possible to make a film bulk acoustic resonator with ease, at low cost.

### BRIEF DESCRIPTION OF THE DRAWINGS

FIG. 1 is a perspective view that shows a film bulk acoustic resonator according to a first embodiment;

FIG. 2 is a cross-sectional view that shows the film bulk acoustic resonator according to the first embodiment;

FIG. 3 is a cross-sectional view (1) that shows a method of making the film bulk acoustic resonator according to the first embodiment;

FIG. 4 is a cross-sectional view (2) that shows the method of making the film bulk acoustic resonator according to the first embodiment;

FIG. 5 is a cross-sectional view (3) that shows the method of making the film bulk acoustic resonator according to the first embodiment;

FIG. 6 is a cross-sectional view (4) that shows the method of making the film bulk acoustic resonator according to the first embodiment;

FIG. 7 is a cross-sectional view (5) that shows the method of making the film bulk acoustic resonator according to the first embodiment;

FIG. 8 is a cross-sectional view (6) that shows the method of making the film bulk acoustic resonator according to the first embodiment;

FIG. 9 is a cross-sectional view (7) that shows the method of making the film bulk acoustic resonator according to the first embodiment;

FIG. 10 is a perspective view that shows a film bulk acoustic resonator according to a second embodiment;

FIG. 11 is a perspective view that shows a film bulk acoustic resonator according to a third embodiment;

FIG. 12 is a cross-sectional view (1) that shows the film bulk acoustic resonator according to the third embodiment; and

FIG. 13 is a cross-sectional view (2) that shows the film bulk acoustic resonator according to the third embodiment.

### DESCRIPTION OF EMBODIMENTS

Non-limiting examples of embodiments of the present disclosure will be described below with reference to the accompanying drawings. Throughout the accompanying drawings, the same or corresponding members or parts will be assigned the same or corresponding reference numerals, and overlapping description will be omitted.

### First Embodiment

### Film Bulk Acoustic Resonator

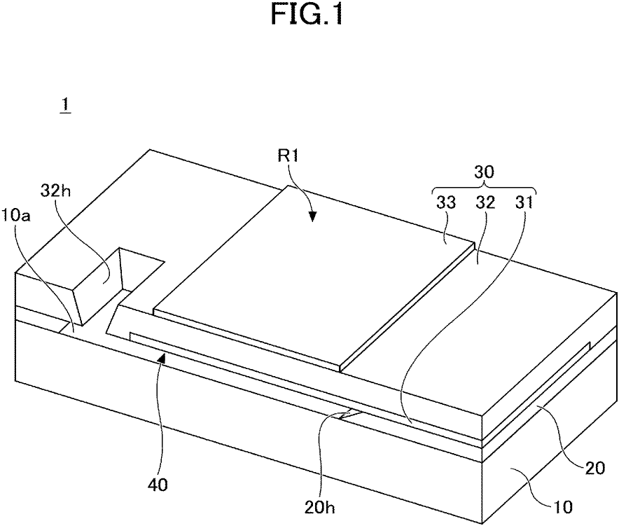

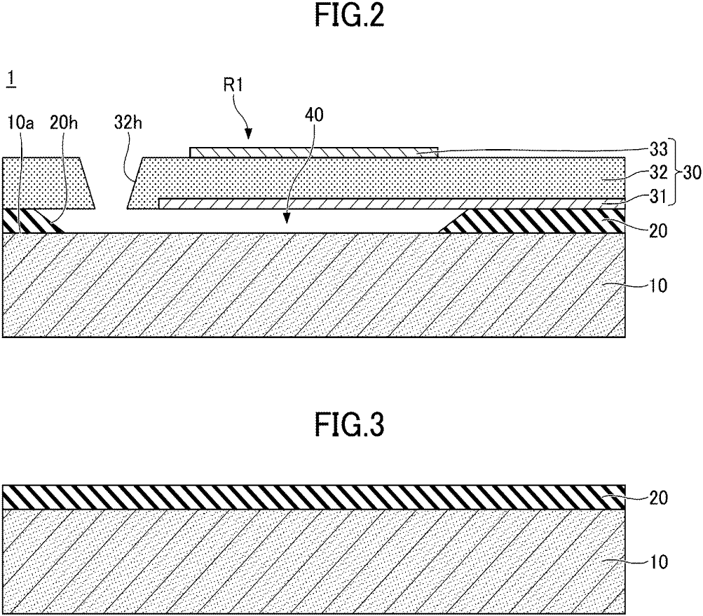

A film bulk acoustic resonator (FBAR) according to a first embodiment will be described with reference to FIG. 1 and FIG. 2. FIG. 1 is a perspective view that shows a film bulk acoustic resonator 1 according to the first embodiment. FIG. 2 is a cross-sectional view that shows the film bulk acoustic resonator 1 according to the first embodiment. The film bulk acoustic resonator 1 has a substrate 10, an oxide film 20, and a laminated film 30.

The substrate 10 has a first main surface 10a. The substrate 10 is, for example, a silicon substrate.

The oxide film 20 is provided over the first main surface 10a. The oxide film 20 has an opening 20h. The oxide film 20 is made of, for example, SiO₂ (silicon dioxide), TEOS (Tetra Ethoxy Silane), SOG (Spin On Glass), BSG (Boro Silicate Glass), PSG (Phospho Silicate Glass), BPSG (Boro Phospho Silicate Glass), and so forth. The thickness of the oxide film 20 is, for example, 200 nm or more, and 2 µm or less.

The laminated film 30 is provided over the oxide film 20. A void 40 is provided between the substrate 10 and the laminated film 30, at a position corresponding to the opening 20h. A laminated film 30 has a lower electrode 31, a piezoelectric layer 32, and an upper electrode 33. The lower electrode 31, the piezoelectric layer 32 and the upper electrode 33 are laminated in this order over the oxide film 20.

The lower electrode 31 is provided over the oxide film 20 and over the substrate 10 via the void 40. When viewed normal to the first main surface 10a, the lower electrode 31 is provided at a position where the lower electrode 31 covers at least part of the void 40. The lower electrode 31 is made of a metallic material such as molybdenum (Mo), tungsten (W), titanium (Ti), gold (Au), platinum (Pt), ruthenium (Ru), and aluminum (Al), and so forth. The thickness of the lower electrode 31 is, for example, 50 nm or more, and 500 nm or less.

The piezoelectric layer 32 is provided on the lower electrode 31, and over the substrate 10, via the void 40. When viewed normal to the first main surface 10a, the piezoelectric layer 32 is provided at a position where the piezoelectric layer 32 covers at least part of the void 40. When viewed normal to the first main surface 10a, the piezoelectric layer 32 has a larger size than the lower electrode 31 and the upper electrode 33. The piezoelectric layer 32 has a through-hole 32h that communicates with the void 40. When viewed normal to the first main surface 10a, the through-hole 32h is provided at a position spaced apart from the lower electrode 31 and the upper electrode 33. The through-hole 32h is formed to penetrate the piezoelectric layer 32, without penetrating the lower electrode 31 and the upper electrode 33. The piezoelectric layer 32 is formed of a piezoelectric material such as aluminum nitride (AlN), lead zirconate titanate (PZT), zinc oxide (ZnO), and so forth. The thickness of the piezoelectric layer 32 is, for example, 250 nm or more, and 2 µm or less.

The upper electrode 33 is provided on the piezoelectric layer 32. The upper electrode 33 is provided so as to include a position facing the lower electrode 31. When viewed normal to the first main surface 10a, the upper electrode 33 is provided at a position where the upper electrode 33 covers at least part of the void 40. The upper electrode 33 is made of the same material as the lower electrode 31, for example. The thickness of the upper electrode 33 is, for example, 50 nm or more, and 500 nm or less.

In this film bulk acoustic resonator 1, the area where the lower electrode 31, the piezoelectric layer 32, and the upper electrode 33 overlap constitutes a resonator R1. In the film bulk acoustic resonator 1, when a voltage is applied to the lower electrode 31 and the upper electrode 33, the piezoelectric layer 32 sandwiched between the lower electrode 31 and the upper electrode 33 vibrates in the thickness direction due to the piezoelectric effect, and thus exhibits electrical resonance characteristics. For example, a bandpass filter is formed by connecting film bulk acoustic resonators 1 in a ladder-like shape.

The film bulk acoustic resonator 1 of the first embodiment described above has: a substrate 10 having a first main surface 10a; an oxide film 20 provided over the first main surface 10a; and a laminated film 30 provided over the oxide film 20 and having a lower electrode 31, a piezoelectric layer 32, and an upper electrode 33 laminated in this order. A void 40 is provided between the substrate 10 and the lower electrode 31, and the piezoelectric layer 32 has a through-hole 32h that communicates with the void 40. By this means, after the laminated film 30 is formed over the oxide film 20 without a step, a void can be formed between the substrate 10 and the laminated film 30 by removing part of the oxide film 20. As a result of this, the film bulk acoustic resonator 1 can be made with ease, at low cost.

Furthermore, according to the film bulk acoustic resonator 1 of the first embodiment, the lower electrode 31 is provided over the substrate 10 with the oxide film 20 interposed therebetween. As a result of this, it is possible to reduce the impact of parasitic elements between devices and wires, without using a high-resistance substrate as the substrate 10.

### Method of Making Film Bulk Acoustic Resonator

The method of making the film bulk acoustic resonator 1 according to the first embodiment will be described with reference to FIG. 3 to FIG. 9. FIG. 3 to FIG. 9 are cross-sectional views that show the method of making the film bulk acoustic resonator 1 according to the first embodiment.

First, as shown in FIG. 3, an oxide film 20 is formed over a substrate 10 by thermal oxidation, chemical vapor deposition (CVD), sputtering, and the like. The thickness of the oxide film 20 is, for example, 200 nm or more, and 2 µm or less.

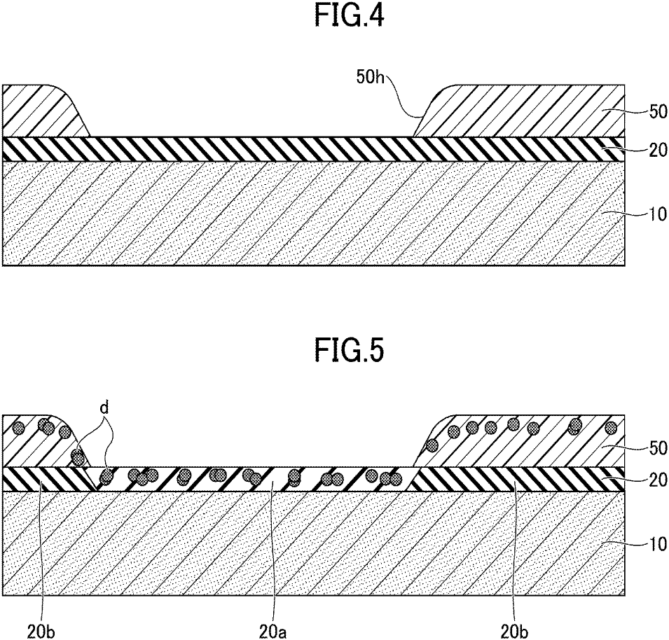

Next, as shown in FIG. 4, a resist 50 having an opening 50h is formed over the oxide film 20 by photolithography. The resist 50 is, for example, a positive photoresist used in making of semiconductor devices. The opening 50h is located in the area where the void 40 is formed. The opening 50h exposes the surface of the oxide film 20.

Next, as shown in FIG. 5, by ion implantation, impurities d are implanted in the oxide film 20, and an implanted area 20a is formed. In the ion implantation, impurities d such as boron (B), phosphorus (P), arsenic (As), antimony (Sb), and so forth are implanted. In the ion implantation, the impurities d are implanted in the area of the oxide film 20 that is exposed from the opening 50h. On the other hand, in the area of the oxide film 20 that is covered with the resist 50, the resist 50 prevents the impurities d from being implanted in the oxide film 20. As a result of this, the area of the oxide film 20 covered with the resist 50 becomes an unimplanted area 50b where the impurities d are not implanted.

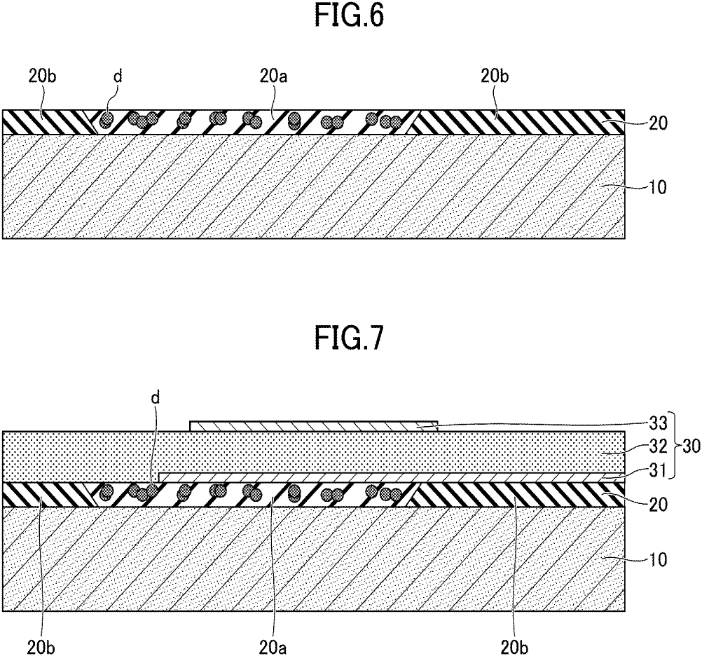

Next, as shown in FIG. 6, the resist 50 is removed by dry ashing, wet etching, and the like. By this means, an implanted area 20a and an unimplanted area 20b are exposed on the surface of the oxide film 20.

Next, as shown in FIG. 7, a laminated film 30 is formed over the oxide film 20, including a lower electrode 31, a piezoelectric layer 32, and an upper electrode 33 in this order. To be more specific, first, a metal layer is formed over the oxide film 20 by CVD, sputtering, and so forth. Next, the lower electrode 31 is formed by processing the metal layer into a desired shape by photolithography and etching. The thickness of the lower electrode 31 is, for example, 50 nm or more and 500 nm or less. Then, the piezoelectric layer 32 is formed over the oxide film 20 and the lower electrode 31 by sputtering, sol-gel, and so forth. The thickness of the piezoelectric layer 32 is, for example, 250 nm or more, and 2 µm or less. Next, a metal layer is formed over the piezoelectric layer 32 by CVD, sputtering, and so forth, and then an upper electrode 33 is formed by processing the metal layer into a desired shape by photolithography and etching. The thickness of the upper electrode 33 is 50 nm or more and 500 nm or less.

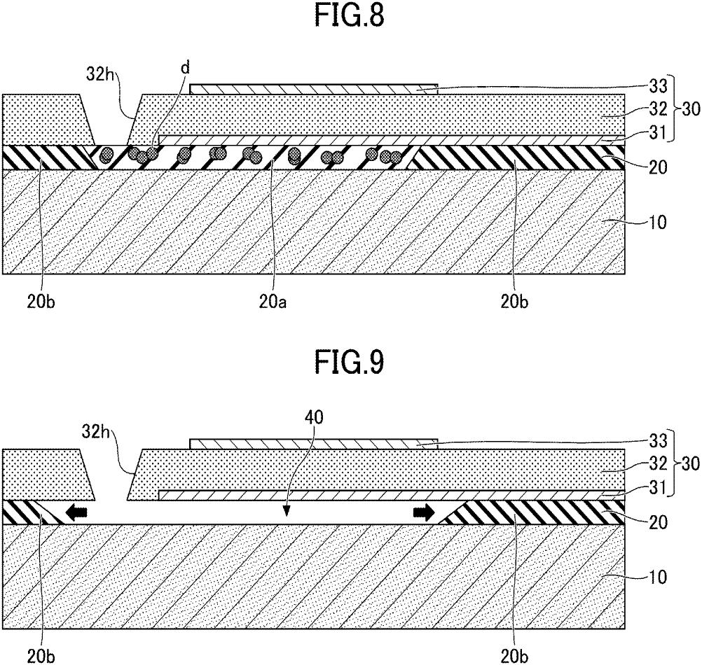

Next, as shown in FIG. 8, by using photolithography and etching, a through-hole 32h is formed, which penetrates the piezoelectric layer 32 in the thickness direction and exposes the implanted area 20a. In plan view normal to the first main surface 10a, the through-hole 32h is formed at a position overlapping the implanted area 20a and spaced apart from the lower electrode 31 and the upper electrode 33.

Next, as shown in FIG. 9, an etchant is introduced from the through-hole 32h. The etchant is a chemical solution having a higher etching rate for the implanted area 20a than for the unimplanted area 20b. Consequently, when the etchant is introduced from the through-hole 32h, etching of the implanted area 20a advances along the first main surface 10a, from directly under the through-hole 32h, as indicated by the arrows in FIG. 9, and the implanted area 20a is removed. As a result of this, a film bulk acoustic resonator 1, having a void 40 that communicates with a through-hole 32h, is produced between the substrate 10 and the laminated film 30. As for the method of removing the implanted area 20a, wet etching using HF (hydrofluoric acid), BHF (buffered hydrofluoric acid), and the like, sacrificial layer etching (vapor layer etching) using anhydrous hydrogen fluoride and alcohol, and the like, can be used. BHF is a mixed solution of HF (hydrofluoric acid) and NH₄F (ammonium fluoride). Note that, although the etchant introduced from the through-hole 32h reaches the unimplanted area 20b when the implanted area 20a is removed, the unimplanted area 20b is not readily etched as compared to the implanted area 20a. As a result of this, the expansion of the void 40 can be limited.

As described above, according to the method of making the film bulk acoustic resonator 1 of the first embodiment, after the laminated film 30 is formed over the oxide film 20 without a step, the void 40 is formed between the substrate 10 and the laminated film 30 by removing part of the oxide film 20. As a result of this, the film bulk acoustic resonator 1 can be made with ease, at low cost.

Furthermore, according to the method of making the film bulk acoustic resonator 1 of the first embodiment, the lower electrode 31, the piezoelectric layer 32, and the upper electrode 33 are formed over the oxide film 20 without a step. As a result of this, the lower electrode 31, the piezoelectric layer 32, and the upper electrode 33 can be prevented from having a portion, such as a bending portion, where stress tends to concentrate.

Furthermore, according to the method of making the film bulk acoustic resonator 1 of the first embodiment, impurities d are implanted in the oxide film 20 by ion implantation to form the implanted area 20a with an increased etching rate, and the void 40 is formed under the laminated film 30 by removing the implanted area 20a by an etchant. Consequently, the location to form the void 40 can be adjusted with ease.

Moreover, according to the method of making the film bulk acoustic resonator 1 of the first embodiment, the void 40 is formed without processing the substrate 10. As a result of this, a film bulk acoustic resonator 1 with little warping and high strength can be made. In contrast with this, when a substrate is processed, the substrate becomes thin, so its strength is likely to decrease, and warping is likely to be produced. In addition, when processing a substrate from the back after a laminated film is formed, the step of forming a protective film or the like needs to be added so as to protect the laminated film and the like on the surface when processing the substrate, and so the manufacturing cost increases.

### Second Embodiment

A film bulk acoustic resonator according to a second embodiment will be described with reference to FIG. 10. FIG. 10 is a perspective view that shows a film bulk acoustic resonator 2 according to the second embodiment.

The film bulk acoustic resonator 2 is different from the film bulk acoustic resonator 1 in having a first resonator R21 and a second resonator R22, and in that an insulated area I is formed between the first resonator R21 and the second resonator R22. Note that, the structure of the first resonator R21 and the second resonator R22 may be substantially the same as the structure of the resonator R1 of the film bulk acoustic resonator 1.

The first resonator R21 and the second resonator R22 are formed on a common substrate 10. The second resonator R22 is formed adjacent to the first resonator R21 with an insulated area I interposed therebetween. The insulated area I is an area where the oxide film 20 and the piezoelectric layer 32 are not present, between the upper electrode 33 of the first resonator R21 and the upper electrode 33 of the second resonator R22. The insulated area I can be formed by the same method as the void 40 described above.

According to the film bulk acoustic resonator 2 of the second embodiment, the insulated area I is provided between the neighboring first resonator R21 and second resonator R22. By this means, it is possible to reduce the parasitic elements and reduce the noise.

### Third Embodiment

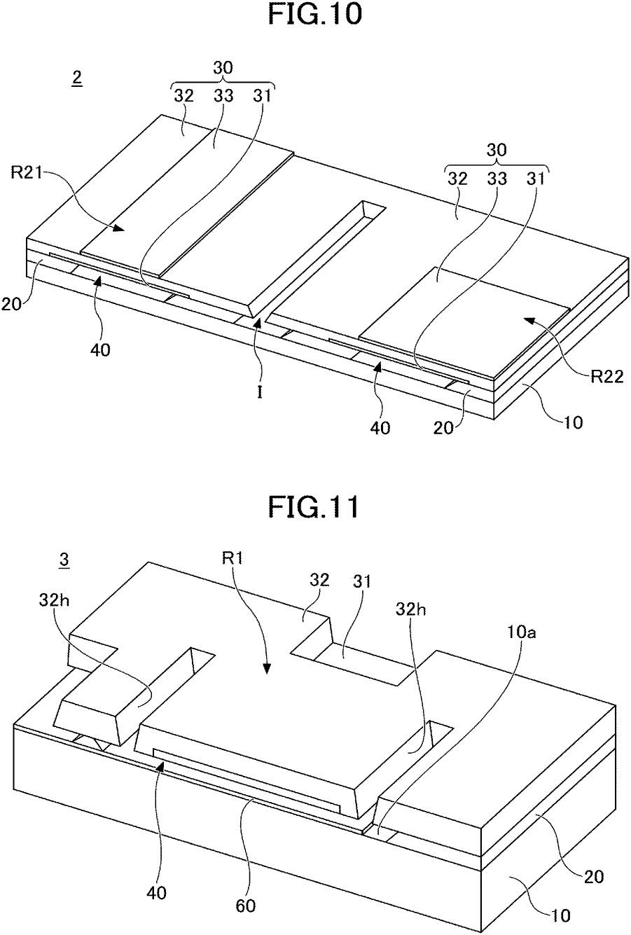

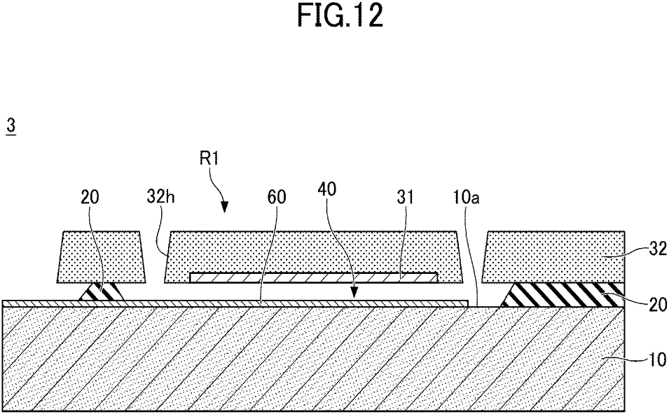

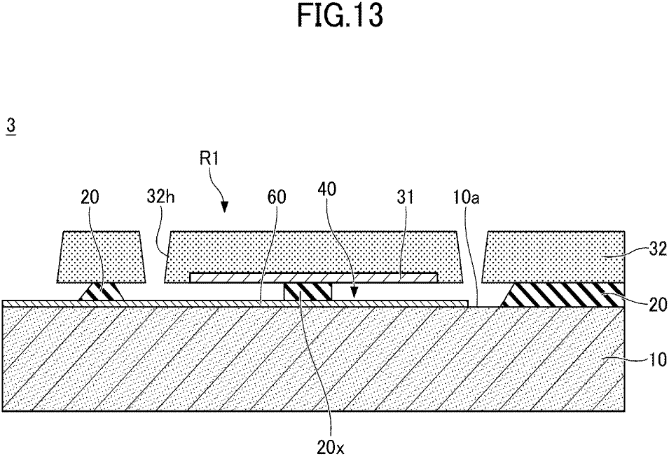

Referring to FIG. 11 to FIG. 13, the film bulk acoustic resonator according to a third embodiment will be described. FIG. 11 is a perspective view that shows a film bulk acoustic resonator 3 according to the third embodiment. FIG. 12 and FIG. 13 are cross-sectional views that show the film bulk acoustic resonator 3 according to the third embodiment. Note that, in FIG. 11 to FIG. 13, the upper electrode 33 is not illustrated.

The film bulk acoustic resonator 3 is different from the film bulk acoustic resonator 1 in having a sensor electrode 60, which is provided to face the lower electrode 31 on the first main surface 10a. Note that the rest of the structure may be substantially the same as that of the film bulk acoustic resonator 1.

The sensor electrode 60 is provided over the first main surface 10a. The sensor electrode 60 is provided to face the lower electrode 31. As a result of this, a void 40 is formed between the lower electrode 31 and the sensor electrode 60. The sensor electrode 60 is made of the same material as the lower electrode 31, for example.

The sensor electrode 60 is formed over a substrate 10 before an oxide film 20 is formed over the substrate 10. The sensor electrode 60 is formed by forming a metal layer over the first main surface 10a by CVD, sputtering, and so forth, and then processing the metal layer into a desired shape by photolithography and etching. The thickness of the sensor electrode 60 is, for example, 50 nm or more and 500 nm or less.

According to the film bulk acoustic resonator 3 of the third embodiment, the sensor electrode 60 facing the lower electrode 31 is provided over the first main surface 10a. By this means, the lower electrode 31, the sensor electrode 60, and the void 40 that is sandwiched between the lower electrode 31 and the sensor electrode 60 form a capacitor structure. When there is an unetched and remaining oxide film 20x between the lower electrode 31 and the sensor electrode 60 (see FIG. 13), the capacitance between the lower electrode 31 and sensor electrode 60 changes, unlike when the oxide film 20x is not present between the lower electrode 31 and the sensor electrode 60. Then, by measuring the capacitance between the lower electrode 31 and the sensor electrode 60, it is possible to determine whether or not the oxide film 20x remains between the lower electrode 31 and the sensor electrode 60. Note that, in the film bulk acoustic resonator 3, the resonator R1 is provided on the substrate 10 through the void 40, and therefore it is difficult to check, with naked eye, whether the oxide film 20x remains between the substrate 10 and the lower electrode 31.

When viewed normal to the first main surface 10a, the sensor electrode 60 is preferably provided so as to include the farthest position from the through-hole 32h in the void 40. The oxide film 20x tends to remain at the farthest position from the through-hole 32h in the void 40. Consequently, by measuring the capacitance between the lower electrode 31 and the sensor electrode 60 so as to include the farthest position from the through-hole 32h, whether or not the oxide film 20x in the void 40 is completely removed can be determined with ease.

Note that, in the above embodiments, the lower electrode 31, the upper electrode 33, and the sensor electrode 60 are examples of the first electrode, the second electrode, and the third electrode, respectively.

The embodiments disclosed herein should be considered illustrative in all respects and not restrictive. The above-described embodiments may be omitted, substituted or modified in various ways without departing from the scope and spirit of the accompanying claims.

What is claimed is:

1. A film bulk acoustic resonator comprising:
a substrate having a first main surface;
an oxide film provided over the first main surface; and
a laminated film provided over the oxide film and including a first electrode, a piezoelectric layer, and a second electrode laminated in this order,
wherein a void where the oxide film is removed is provided between the substrate and the first electrode, and
wherein the piezoelectric layer has a through-hole that communicates with the void.

2. The film bulk acoustic resonator according to claim 1, wherein, in plan view normal to the first main surface, the first electrode and the second electrode cover at least part of the void, and
wherein the through-hole is situated apart from the first electrode and the second electrode.

3. The film bulk acoustic resonator according to claim 1, further comprising a third electrode provided over the first main surface so as to face the first electrode.

4. A method of making a film bulk acoustic resonator, comprising:
forming an oxide film over a substrate;
forming an implanted area where impurities are implanted in the oxide film;
forming a laminated film including a first electrode, a piezoelectric layer, and a second electrode in this order, over the oxide film including the implanted area;
forming a through-hole by penetrating the piezoelectric layer, and exposing the implanted area; and
forming a void below the laminated film by introducing an etchant from the through-hole and removing the implanted area.

5. The method of making the film bulk acoustic resonator according to claim 4, wherein the forming of the implanted area includes:
forming a resist having an opening, over the oxide film;
implanting, by ion implantation, impurities into the oxide film over which the resist is formed; and
removing the resist after the impurities are implanted.
